(19) United States
(12) Patent Application Publication
(10) Pub. No.: US 2025/0036022 A1
(43) Pub. Date: Jan. 30, 2025

(54) OPTICAL PROXIMITY CORRECTION (OPC) METHOD AND MASK MANUFACTURING METHOD COMPRISING OPC METHOD

(71) Applicant: Samsung Electronics Co., Ltd., Suwon-si (KR)

(72) Inventors: Sanghwa Woo, Suwon-si (KR); Wooseok Kim, Suwon-si (KR); Bongkeun Kim, Suwon-si (KR); Sanghwa Lee, Suwon-si (KR)

(21) Appl. No.: 18/632,558

(22) Filed: Apr. 11, 2024

(30) Foreign Application Priority Data
Jul. 24, 2023 (KR) 10-2023-0096407

(51) Int. Cl. G03F 1/36

(52) U.S. Cl. CPC G03F 1/36

(57) ABSTRACT

Provided is an optical proximity correction (OPC) method including receiving a design layout for a target pattern to be formed on a substrate, obtaining a first OPC pattern by performing a baseline OPC on the design layout, and obtaining a second OPC pattern by curving the first OPC pattern.

### CROSS-REFERENCE TO RELATED APPLICATION

This application is based on and claims priority under 35 U.S.C. § 119 to Korean Patent Application No. 10-2023-0096407, filed on Jul. 24, 2023, in the Korean Intellectual Property Office, the disclosure of which is incorporated by reference herein in its entirety.

### BACKGROUND

The inventive concepts relate to a mask manufacturing method, and more particularly, to an optical proximity correction (OPC) method and a mask manufacturing method using the OPC method.

In a semiconductor process, a photolithography process using a mask may be performed to form a pattern on a semiconductor substrate such as a wafer. Simply defined, a mask can be said to be a pattern transfer material in which a pattern shape of an opaque material is formed on a transparent base material. To briefly explain a manufacturing process for the mask, first, a required circuit is designed, a layout for the circuit is designed, and then, design data obtained through OPC is transferred as mask tape-out (MTO) design data. Thereafter, mask data preparation (MDP) may be performed based on the MTO design data, and an exposure process, etc. may be performed on a substrate for a mask.

### SUMMARY

The inventive concepts provide an optical proximity correction (OPC) method in which a pattern with a critical pitch may be implemented through single exposure patterning, and a mask manufacturing method including the OPC method.

In addition, the objective to be resolved by the inventive concepts is not limited to the objective mentioned above, and other objectives may be clearly understood by a person skilled in the art from the following descriptions.

According to some aspects of the inventive concepts, there is provided an optical proximity correction (OPC) method including receiving a design layout for a target pattern to be formed on a substrate, obtaining a first OPC pattern by performing a baseline OPC on the design layout, and obtaining a second OPC pattern by curving the first OPC pattern.

According to some aspects of the inventive concepts, there is provided an OPC method including receiving a design layout for a target pattern to be formed on a substrate, obtaining a first OPC pattern by performing a baseline OPC on the design layout, obtaining a second OPC pattern by curving a line-end of the first OPC pattern, obtaining a simulation contour for the second OPC pattern, and determining whether a defect is present in the simulation contour.

According to some aspects of the inventive concepts, there is provided a mask manufacturing method including performing an OPC method to obtain an OPCed design layout for a target pattern to be formed on a substrate, transferring data on the OPCed design layout as mask tape-out (MTO) design data, preparing mask data based on the MTO design data, and performing an exposure on a substrate for a mask based on the mask data, wherein the performing of the OPC method includes receiving a design layout for the target pattern to be formed on the substrate, obtaining a first OPC pattern by performing a baseline OPC on the design layout, and obtaining a second OPC pattern by curving opposing line-ends of the first OPC pattern.

### BRIEF DESCRIPTION OF THE DRAWINGS

Embodiments of the inventive concepts will be more clearly understood from the following detailed description taken in conjunction with the accompanying drawings in which:

FIG. 1 is a flowchart schematically illustrating an optical proximity correction (OPC) method according to some embodiments;

FIG. 2 is a conceptual diagram illustrating a target pattern in a line and space form and a first OPC pattern based on a baseline OPC result in an operation of obtaining the first OPC pattern, according to some embodiments;

FIG. 3 is a conceptual diagram illustrating a first OPC pattern and a second OPC pattern in an operation of obtaining the second OPC pattern, according to some embodiments;

FIG. 4 is a flowchart schematically illustrating an OPC method according to some embodiments;

FIG. 5 is a flowchart schematically illustrating a method of performing line-end curving, according to some embodiments;

FIG. 6 is a conceptual diagram illustrating a first OPC pattern and a second OPC pattern in an operation of obtaining the second OPC pattern, according to some embodiments;

FIGS. 7A and 7B are scanning electron microscope (SEM) pictures showing defects for line patterns with critical pitch;

FIGS. 8 and 9 are conceptual diagrams for describing concepts of single exposure patterning and double exposure patterning;

FIGS. 10A, 10B, 10C, and 10D are conceptual diagrams of a design layout for a target pattern, an OPC pattern according to the OPC method of the comparative example, and an OPC pattern according to the OPC method of the present embodiments; and

FIG. 11 is a flowchart schematically illustrating a process of a mask manufacturing method including an OPC method, according to some embodiments.

### DETAILED DESCRIPTION

Hereinafter, example embodiments are described in detail with reference to accompanying drawings. In the drawings, the same reference characters are used for the same elements, and redundant descriptions thereof are omitted herein.

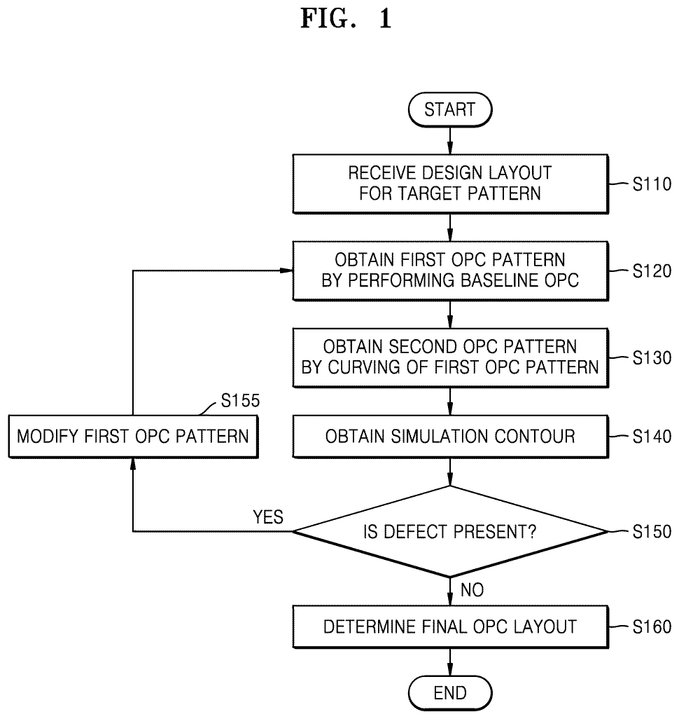

FIG. 1 is a flowchart schematically illustrating an optical proximity correction (OPC) method according to some embodiments.

Referring to FIG. 1, in the OPC method of the present embodiment, first, a design layout for a target pattern to be formed on a substrate may be received in operation S110. Here, the target pattern may refer to a pattern to be formed on a silicon (Si) substrate such as a wafer. In other words, a pattern on a mask may be transferred to the substrate through an exposure process to form a target pattern on the substrate. Meanwhile, the pattern on the mask may be scaled down and projected and transferred onto a wafer, and the pattern on the mask may have a larger size than the target pattern on the substrate.

The design layout may refer to a layout of the pattern on the mask corresponding to the target pattern. Due to the nature of the exposure process, a shape of the target pattern on the wafer and a pattern on an actual mask used in the exposure process may be different from each other. However, a shape of an initial design layout for the pattern on the mask may be substantially the same as the shape of the target pattern.

Meanwhile, in the OPC method of the present embodiment, the target pattern may include a line and space form. The line and space form may allow edges to be composed only of straight lines. Accordingly, the design layout for the target pattern in the line and space form may correspond to a right-angled design layout. For reference, in the OPC method of the present embodiment, the target pattern may be, for example, an after clean inspection (ACI) target pattern.

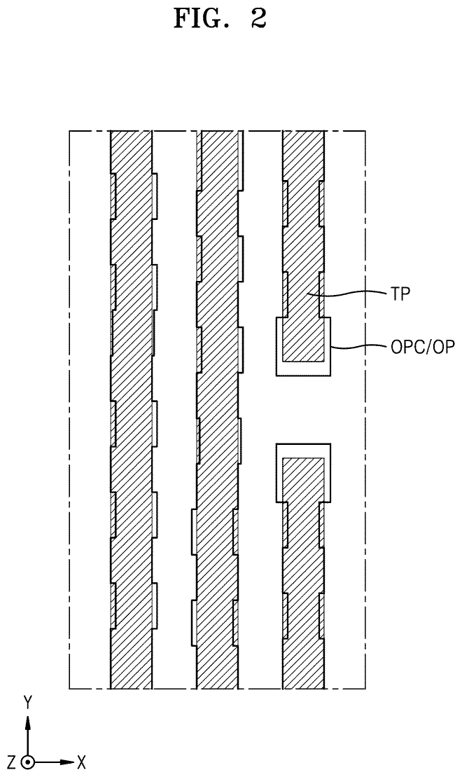

After the design layout is received, a first OPC pattern (OPC/OP in FIG. 2) may be obtained by performing a baseline OPC on the design layout, in operation S120. The baseline OPC refers to common OPC for implementing patterning closest to a target pattern on the substrate. The first OPC pattern (OPC/OP in FIG. 2) is described in detail with reference to FIG. 2.

FIG. 2 is a conceptual diagram illustrating a target pattern in a line and space form and a first OPC pattern based on a baseline OPC result in an operation of obtaining the first OPC pattern, according to some embodiments.

Referring to FIG. 2, a hatched portion may correspond to a target pattern TP in a line and space form, or a design layout corresponding thereto (hereinafter, collectively referred to as a “target pattern”). The target pattern TP may include four line patterns, and line-ends of two adjacent line patterns in a second horizontal direction (Y direction) are shown on the right-hand side of FIG. 2. The two line-ends may face each other. Meanwhile, outer straight lines surrounding the target pattern TP may correspond to segments of the first OPC pattern (OPC/OP).

In the present specification, a direction parallel to a main surface of the substrate may be referred to as a horizontal direction (X direction and/or Y direction), and a direction perpendicular to the horizontal direction (X direction and/or Y direction) may be referred to as a vertical direction (Z direction).

In a case of a target pattern in a line and space form, the first OPC pattern (OPC/OP), which is a result after baseline OPC for the design layout, may include a hammer head shape and a jog shape. Specifically, in the first OPC pattern (OPC/OP) after baseline OPC, a line-end of a line pattern may have a hammer head shape, and a side line of a line pattern may be divided into small segments to become a jog shape. For reference, a segment may also be referred to as a fragment, and may refer to a line of a straight line shape corresponding to an edge of a design layout, or a data for the line. The edge of the design layout may be divided into a plurality of segments according to a certain dividing rule. A length of a segment or a dividing rule may be set by a user performing an OPC method.

The baseline OPC may further include a design rule check (DRC) operation. The DRC operation may include an operation of determining whether the first OPC pattern (OPC/OP) complies with designated design rules.

For reference, the OPC method refers to a method of, when an optical proximity effect (OPE) due to the influence between neighboring patterns occurs in an exposure process as patterns are miniaturized, suppressing, to overcome the above, the OPE by correcting a layout of a pattern. Such an OPC method may be largely divided into two methods: one is a rule-based OPC method, and the other is a simulation-based or model-based OPC method. For example, the OPC method of the present embodiment may be a model-based OPC method. The model-based OPC method may be advantageous in terms of time and cost because only measurement results of representative patterns are used without the need to measure all of a large number of test patterns.

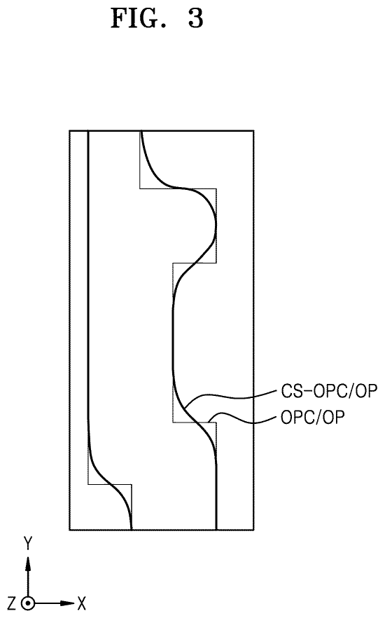

Returning to FIG. 1, after the first OPC pattern (OPC/OP) is obtained through the baseline OPC, a second OPC pattern (CS-OPC/OP in FIG. 3) may be obtained by performing curving on the first OPC pattern (OPC/OP), in operation S130. The second OPC pattern is described in detail with reference to FIG. 3.

FIG. 3 is a conceptual diagram illustrating a first OPC pattern and a second OPC pattern in an operation of obtaining the second OPC pattern, according to some embodiments.

Referring to FIG. 3, for example, operation S130 of FIG. 1 may include an operation of rounding (or curvilinear-izing) corners of each first OPC pattern (OPC/OP). The second OPC pattern (CS-OPC/OP) obtained by performing curving on the first OPC pattern (OPC/OP) may also be referred to as a curved shape (CS)-OPC pattern (CS-OPC/OP). Accordingly, the CS-OPC pattern (CS-OPC/OP) may include a plurality of corner-rounded patterns. In other words, the CS-OPC pattern (CS-OPC/OP) may include edges having a curved line shape. Accordingly, the first OPC pattern (OPC/OP) may include straight line edges (i.e., straight edges), and the second OPC pattern (CS-OPC/OP) may include curved edges.

In the present specification, “curving”, “curvilinear-izing”, and “rounding” may have substantially the same meaning. In more detail, “curving” as used herein with respect to a corner may mean that the corner is modified to be curvilinear or round.

For a method of corner-rounding the first OPC pattern (OPC/OP), a curvature-based method may be used. The curvature-based corner-rounding method may include an operation of recognizing a corner of a target pattern, an operation of generating a curvature for the recognized corner, and an operation of modifying the target pattern with a reference curvature. In the curvature-based corner-rounding method, a short segment is formed along an edge of a shape with a large curvature, and a long segment may be generated along an edge of a shape with a small curvature. In more detail, in the operation of generating the curvature for the recognized corner, for example, a Bézier curve algorithm may be used.

However, the method of corner-rounding the first OPC pattern (OPC/OP) is not limited to that described above. For example, corner-rounding may be performed based on machine learning, or in some other embodiments, the first OPC pattern (OPC/OP) may be divided into a plurality of points, and corner-rounding may be performed based on each of the points.

Returning to FIG. 1, after the CS-OPC pattern (CS-OPC/OP) is obtained, a simulation contour for the CS-OPC pattern (CS-OPC/OP) may be obtained in operation S140. That is, after the second OPC pattern (CS-OPC/OP) is obtained, a simulation contour for the second OPC pattern (CS-OPC/OP) may be obtained in operation S140. For example, the contour may be extracted through simulation by inputting data for the CS-OPC pattern (CS-OPC/OP) to an OPC model. For reference, in the OPC model, various basic data may be input as input data. Here, the basic data may include data for the CS-OPC pattern (CS-OPC/OP). In addition, the basic data may include information data such as a thickness, refractive index, dielectric constant for photoresist (PR), and data of a source map for a shape of an illumination system. However, the basic data is not limited to the example data described above. Ultimately, the simulation contour is a result obtained through simulation using the OPC model and may correspond to a shape of the target pattern TP formed on a wafer in an exposure process using a mask. Accordingly, making the simulation contour as similar as possible to the shape of CS-OPC pattern (CS-OPC/OP) may correspond to the purpose of the OPC method.

According to some embodiments, before the simulation contour for the CS-OPC pattern (CS-OPC/OP) is obtained, a DRC operation for the CS-OPC pattern (CS-OPC/OP) may be further included.

After the simulation is performed, it is determined whether defects are present in the simulation contour, in operation S150. Here, the defects may correspond to a case in which a root mean square (RMS) for a critical dimension (CD) error is greater than a set reference value, a case in which electric potential energy (EPE) is greater than a set reference value, a case in which a pinch-off (P/O) defect is present, a case in which a bridge effect is present, etc. In addition, when other items are present in the simulation, cases where the corresponding items deviate from a reference may also correspond to defects. Meanwhile, according to some embodiments, operation S150 of determining whether defects are present may be included in operation S140 of obtaining the simulation contour.

When defects are present (YES), the process proceeds to operation S120 of obtaining the first OPC pattern (OPC/OP) through baseline OPC. Meanwhile, before operation S120 of obtaining the first OPC pattern (OPC/OP) through baseline OPC, a cause of the defects may be analyzed, and the cause may be reflected in the OPC model. For example, operation S155 of modifying the first OPC pattern (OPC/OP) may be included.

When defects are not present (NO), a CS-OPC layout including the corresponding CS-OPC pattern (CS-OPC/OP) may be determined as a final OPC layout, in operation S160. That is, when defects are not present (NO), a CS-OPC layout including the corresponding second OPC pattern (CS-OPC/OP) may be determined as a final OPC layout, in operation S160. The final OPCed layout may correspond to design data of the mask. Thereafter, the final OPCed layout may be transferred to a mask production team as mask tape-out (MTO) design data for mask production. For example, the final OPCed layout may refer to a final layout that has been optical proximity corrected (OPCed) based on the OPC method of the present embodiment.

The OPC method of the present embodiment may include a CS-OPC process for curving an OPC pattern. Accordingly, the OPC method of the present embodiment may ensure sufficient production margin for a target pattern. Specifically, the OPC method of the present embodiment may ensure sufficient P/O margin and line bridge L/B margin for a target pattern having a critical pitch, compared to common OPC, for example, the baseline OPC method, and may also ensure sufficient P/O margin in other line patterns adjacent to the line-ends. As a result, the OPC method of the present embodiment may allow a target pattern of a critical pitch to be implemented through single exposure patterning, and in particular, may allow the target pattern of the critical pitch to be implemented through single exposure patterning in an extreme ultra-violet (EUV) process.

For reference, in a case of patterns having a critical pitch in the EUV process, it may be impossible to ensure a mass production margin without defects such as P/O and bridge due to limitations in the semiconductor process. Accordingly, in the EUV process, a double exposure patterning process or double patterning process may be generally applied to patterns of a critical pitch to ensure a mass production margin and yield. The double patterning process may also be referred to as a litho-etching-litho-etching (LELE) process based on a process. In addition, in order to form patterns of a critical pitch, triple patterning and/or quadruple patterning other than double patterning may also be used to form patterns of a critical pitch. However, when a double patterning process is used, the number of masks and exposure processes increase correspondingly, which may be very disadvantageous in terms of cost and time. On the other hand, the OPC method of the present embodiment may ensure a sufficient mass production margin, such as a P/O margin and bridge margin, and yield for a target pattern of a critical pitch, as described above, so that a target pattern of a critical pitch may be implemented through a single exposure patterning or single patterning process. In addition, when the OPC method ensures a margin, it may mean substantially the same thing as when the OPC method allows production of a mask capable of ensuring a margin.

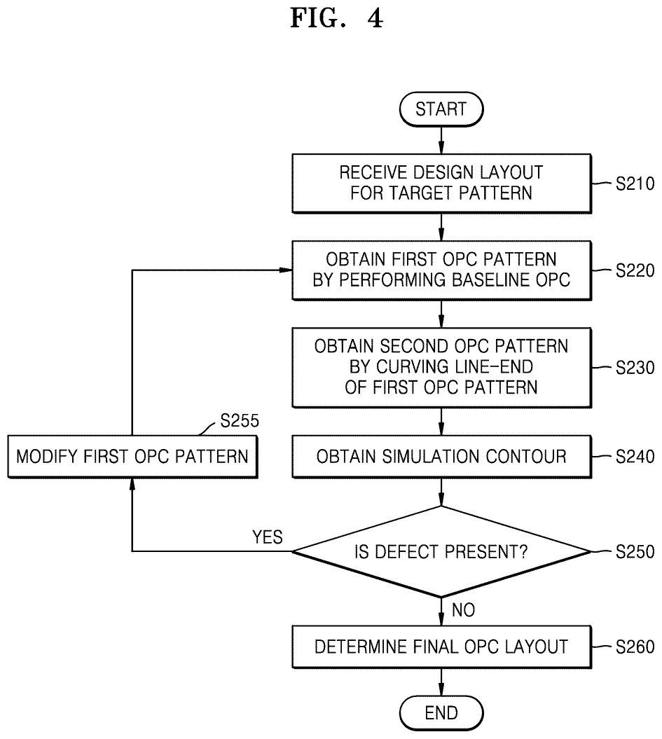

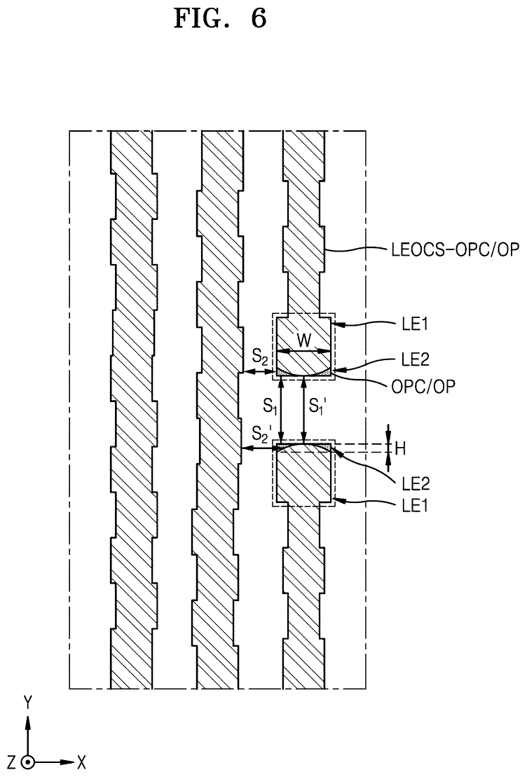

FIG. 4 is a flowchart schematically illustrating an OPC method according to some embodiments. Descriptions are provided with reference to FIGS. 1 to 3 together with FIG. 4. The OPC method of the present embodiment may be different from the OPC method of FIG. 1 in that, in the OPC method of the present embodiment, curving may be performed only at a line-end of a first OPC pattern (e.g., OPC/OP in FIG. 6), whereas in the OPC method of FIG. 1, curving may be performed on an entire area of a first OPC pattern (e.g., OPC/OP in FIG. 3).

Referring to FIG. 4, first, a design layout for a target pattern to be formed on a substrate is received in operation S210. Thereafter, the first OPC pattern (OPC/OP) may be obtained by performing a baseline OPC on the design layout, in operation S220. Operations S210 and S220 in FIG. 4 are substantially the same as operations S110 and S120 in FIG. 1, respectively, and thus detailed descriptions thereof are omitted.

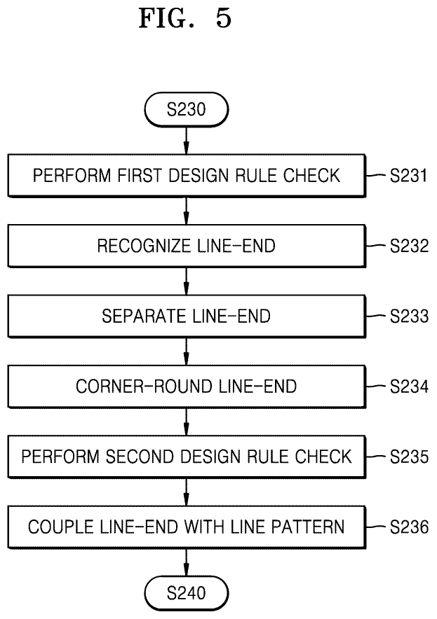

Thereafter, a second OPC pattern (LEOCS-OPC/OP in FIG. 6) may be obtained by performing line-end only curved shape (LEOCS) on the first OPC pattern (OPC/OP), in operation S230. For example, operation S230 may include an operation of performing line-end corner-rounding (or curvilinear-izing) on each first OPC pattern (OPC/OP). The second OPC pattern (LEOCS-OPC/OP) obtained by performing line-end corner-rounding on the first OPC pattern (OPC/OP) may also be referred to as an LEOCS-OPC pattern (LEOCS-OPC/OP). Accordingly, the LEOCS-OPC pattern (LEOCS-OPC/OP) may include a plurality of patterns of which line-ends are corner-rounded. Accordingly, the first OPC pattern (OPC/OP) may include straight line edges (i.e., straight edges), and the second OPC pattern (LEOCS-OPC/OP) may include straight line edges (i.e., straight edges) and curved edges. A method of performing line-end curving is described in detail with reference to FIGS. 5 and 6.

FIG. 5 is a flowchart schematically illustrating a method of performing line-end curving, according to some embodiments. FIG. 6 is a conceptual diagram illustrating a first OPC pattern and a second OPC pattern in an operation of obtaining the second OPC pattern, according to some embodiments.

Referring to FIGS. 5 and 6, in the method of performing the line-end curving, first, a first DRC is performed on the obtained first OPC pattern (OPC/OP), in operation S231. The first DRC operation may include an operation of determining whether the first OPC pattern (OPC/OP) complies with designated design rules.

For example, in the first DRC operation, edges and corners of each of the first OPC pattern (OPC/OP) may be determined. For example, in the first DRC operation, a dimension and/or relative position of each of the first OPC pattern (OPC/OP) may be determined. For example, the first DRC operation may include an operation of separating each of the first OPC pattern (OPC/OP) into a plurality of polygons and an operation of modifying positions of the plurality of polygons. Operation S231 may be performed in order to later perform operation S232 of recognizing a line-end.

Thereafter, a line-end may be recognized in operation S232. The line-end may be recognized through a length by which each first OPC pattern (OPC/OP) is spaced apart in the horizontal direction (X direction and/or Y direction). For example, the line-end of the first DRC operation may be recognized based on an edge, corner, dimension, and/or relative position of each first OPC pattern (OPC/OP) determined in the first DRC operation.

In FIG. 6, by way of example, the first OPC pattern (OPC/OP) includes four line patterns, and line-ends of two lines adjacent to each other in the second horizontal direction (Y direction) are shown on the right-hand side of FIG. 6. In other words, FIG. 6 shows two line-ends that are spaced apart from each other in the second horizontal direction (Y direction) and face each other. However, a shape and arrangement of the first OPC pattern (OPC/OP) may be variously modified. In other words, a shape and arrangement of the target pattern TP may be variously modified.

In FIG. 6, two line patterns spaced apart from each other in the second horizontal direction (Y direction) may be spaced apart from each other by a first distance S₁. In addition, a portion at the bottom of each of the two line patterns may be spaced apart from a line pattern adjacent thereto in a first horizontal direction (X direction) by a second distance S₂.

In other words, a line-end may be determined according to the first distance S₁ spaced apart in a direction parallel to an extension direction of each line pattern and the second distance S₂ spaced apart in a horizontal direction (X direction and/or Y direction) different from the direction described above. For example, a line-end (e.g., included in one of the two line patterns) may be recognized by the first distance S₁ and the second distance S₂, the first distance S₁ may be a distance between the line-end and an adjacent line-end (e.g., included in the other one of the two line patterns) in the second horizontal direction (Y direction) parallel to an extension direction of the first OPC pattern (OPC/OP), and the second distance S₂ may be a distance between the line-end and an adjacent line pattern in the first horizontal direction (X direction) different from the second horizontal direction (Y direction).

In some other embodiments, a line-end may be determined according to gradient-based methods such as Sobel, Roberts, and/or Canny methods. Alternatively, a line-end may be determined according to a convolution-based method, a machine learning-based method, and/or a rule-based method. A method of recognizing a line-end may be variously modified.

Thereafter, the line-end may be separated in operation S233. In the OPC method of FIG. 4, only the line-end may be curved, and thus an operation of separating the line-end may be included. In FIG. 6, by way of example, line-ends separated by squares having dotted outlines are shown. As used herein, a line pattern including a line-end may be referred to as a separated line pattern after the line-end is separated. In other words, the line pattern including the line-end may include the separated line-end and a separated line pattern.

The separated line-end may include a first portion LE1 coupled to (or connected to) the separated line pattern later (and/or previously), and a second portion LE2 facing a different line-end. The first portion LE1 and the second portion LE2 may be spaced apart from each other in an extension direction of the line pattern. For example, in FIG. 6, because the line pattern extends in the second horizontal direction (Y direction), the first portion LE1 and the second portion LE2 may be spaced apart from each other in the second horizontal direction (Y direction). For example, in FIG. 6, the first portion LE1 and the second portion LE2 may be adjacent to each other in the second horizontal direction (Y direction).

Thereafter, the line-end may be corner-rounded in operation S234. For example, the second portion LE2 of the line-end may be corner-rounded. As a method of corner-rounding a line-end of the first OPC pattern (OPC/OP), the curvature-based method described above with reference to FIG. 3 may be used. The curvature-based corner-rounding method may include an operation of recognizing a corner of a target pattern, an operation of generating a curvature for the recognized corner, and an operation of modifying the target pattern with a reference curvature. In the curvature-based corner-rounding method, a short segment is formed along an edge of a shape with a large curvature, and a long segment may be generated along an edge of a shape with a small curvature. In more detail, in the operation of generating the curvature for the recognized corner, for example, a Bézier curve algorithm may be used.

However, the method of corner-rounding the line-end of the first OPC pattern (OPC/OP) is not limited to that described above. For example, a line-end of the first OPC pattern (OPC/OP) may be corner-rounded based on machine learning, or in some other embodiments, the line-end of the first OPC pattern (OPC/OP) may be divided into a plurality of points so that corner-rounding may be performed based on each of the points.

In some embodiments, the first distance S₁, which is a separation distance between adjacent line-ends in the first OPC pattern (OPC/OP), may be equal to a first distance S₁′, which is a separation distance between adjacent line-ends in the second OPC pattern (LEOCS-OPC/OP). In some other embodiments, the first distance S₁, which is a separation distance between adjacent line-ends in the first OPC pattern (OPC/OP), may be greater than the first distance S₁′, which is a separation distance between adjacent line-ends in the second OPC pattern (LEOCS-OPC/OP).

In addition, a second distance S₂′, which is a distance between a line-end in the second OPC pattern (LEOCS-OPC/OP) and an adjacent line pattern, may be increased compared to the second distance S₂, which is a distance between a line-end in the first OPC pattern (OPC/OP) and an adjacent line pattern. For example, the second distance S₂′ may be greater than the second distance S₂. When the second distance S₂′ in the second OPC pattern (LEOCS-OPC/OP) is increased compared to the second distance S₂ in the first OPC pattern (OPC/OP), the possibility of bridge defects occurring may be reduced. In some other embodiments, the second distance S₂′ may be equal to the second distance S₂.

For example, a height H of a curved line-end (e.g., a corner-rounded line-end) may be less than half a width W of a line pattern. The height H of the curved line-end may mean a distance from a line-end to an end point of a curved edge in a direction parallel to an extension direction of a line pattern (e.g., the second horizontal direction (Y direction) in FIG. 6). In addition, the width W of a line pattern may be substantially equal to a width of the line-end. In other words, the height H of the curved line-end may be less than or equal to half a width of the curved line-end. For example, when the width W of the line pattern is about 20 nanometers or less, the height H of the curved line-end may be about 10 nanometers or less. In FIG. 6, the width W of the line pattern (and the width of the curved line-end) may be taken in the first horizontal direction (X direction).

Thereafter, a second DRC may be performed on the LEOCS-OPC pattern (LEOCS-OPC/OP), in operation S235. That is, a second DRC may be performed on the second OPC pattern (LEOCS-OPC/OP), in operation S235. The second DRC may identify appropriateness of a corner-rounding process for a line-end.

Thereafter, a corner-rounded line-end and a line pattern may be coupled to each other, in operation S236. In other words, a first portion (LE1 in FIG. 6) of the corner-rounded line-end may be connected to a separated line pattern. Accordingly, corner-rounding may be performed only on the line-end.

Returning to FIG. 4, thereafter, operation S240 of obtaining a simulation contour for the second OPC pattern (LEOCS-OPC/OP) and operation S250 of determining whether defects are present in the simulation contour may be performed.

Operations S240 and S250 of FIG. 4 are substantially the same as operations S140 and S150 of FIG. 1, respectively, except that input data is the LEOCS-OPC pattern (LEOCS-OPC/OP) instead of the CS-OPC pattern (CS-OPC/OP), and thus detailed descriptions thereof are omitted.

When defects are present (YES), the process proceeds to operation S220 of obtaining the first OPC pattern (OPC/OP) through baseline OPC. Meanwhile, before operation S220 of obtaining the first OPC pattern (OPC/OP) through baseline OPC, a cause of the defects may be analyzed, and the cause may be reflected in the OPC model. For example, operation S255 of modifying the first OPC pattern (OPC/OP) may be included.

When defects are not present (NO), an LEOCS-OPC layout including the corresponding LEOCS-OPC pattern (LEOCS-OPC/OP) may be determined as a final OPC layout, in operation S260. That is, when defects are not present (NO), an LEOCS-OPC layout including the corresponding second OPC pattern (LEOCS-OPC/OP) may be determined as a final OPC layout, in operation S260. The final OPCed layout may correspond to design data of the mask. Thereafter, the final OPCed layout may be transferred to a mask production team as MTO design data for mask production.

The OPC method of the present embodiment may include an LEOCS process for curving line-end portions of line patterns adjacent to each other. In order to selectively curve only the line-end portions, the OPC method of the present embodiment may include a process of separating a line-end.

Accordingly, the OPC method of the present embodiment may ensure sufficient production margin for a target pattern. Specifically, the OPC method of the present embodiment may ensure sufficient P/O margin and line bridge L/B margin for a target pattern having a critical pitch, compared to common OPC, for example, the baseline OPC method, and may also ensure sufficient P/O margin in other line patterns adjacent to the line-ends. As a result, the OPC method of the present embodiment may allow a target pattern of a critical pitch to be implemented through single exposure patterning, and in particular, may allow the target pattern of the critical pitch to be implemented through single exposure patterning in a EUV process. Meanwhile, as described above, the OPC method of the present embodiment may include a process of distorting a target pattern through a process of curving each of the line-ends of the line patterns. That is, the OPC method of the present embodiment may include a process of distorting a target pattern through a process of curving opposing line-ends of each of the line patterns.

For reference, in a case of patterns having a critical pitch in the EUV process, it may be impossible to ensure a mass production margin without defects such as P/O and bridge due to limitations in the semiconductor process. Accordingly, in the EUV process, a double exposure patterning process or double patterning process may be generally applied to patterns of a critical pitch to ensure a mass production margin and yield. The double patterning process may also be referred to as an LELE process based on a process. In addition, in order to form patterns of a critical pitch, triple patterning and/or quadruple patterning other than double patterning may also be used to form patterns of a critical pitch. However, when a double patterning process is used, the number of masks and exposure processes increase correspondingly, which may be very disadvantageous in terms of cost and time. On the other hand, the OPC method of the present embodiment may ensure a sufficient mass production margin, such as a P/O margin and bridge margin, and yield for a target pattern of a critical pitch, as described above, so that a target pattern of a critical pitch may be implemented through a single exposure patterning or single patterning process. In addition, when the OPC method ensures a margin, it may mean substantially the same thing as when the OPC method allows production of a mask capable of ensuring a margin.

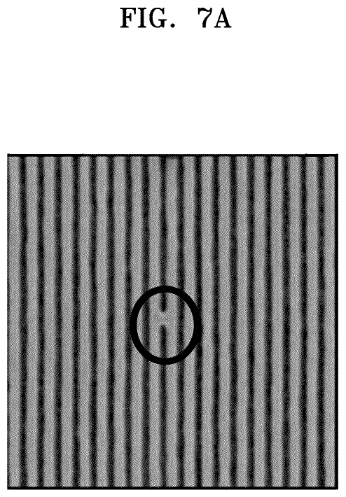

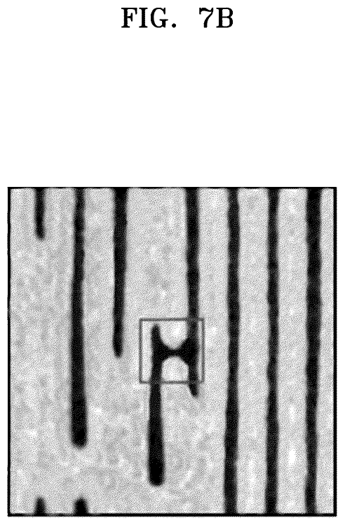

FIGS. 7A and 7B are scanning electron microscope (SEM) pictures showing defects for line patterns with critical pitch. FIG. 7A is a SEM picture of a P/O defect, and FIG. 7B is a SEM picture of a bridge defect. The SEM pictures of FIGS. 7A and 7B show defects that have occurred in a single exposure patterning process due to EUV for line patterns of a critical pitch.

Referring to FIG. 7A, a P/O defect may occur at a line-end. In FIG. 7A, it is shown that a P/O defect is formed inside a circular shape. The P/O defect may mean that a plurality of line patterns that are supposed to be connected to each other are spaced apart from each other. In other words, when a P/O defect occurs, a plurality of line patterns meant to be connected to each other may be opened. The P/O defect may cause disconnection of electrical signals and/or reduced yield of semiconductor devices.

Referring to FIG. 7B, a bridge defect may occur at a line-end of a line pattern. In FIG. 7B, it is shown that a bridge defect is formed inside a rectangular shape. For example, a bridge defect may occur between a line-end and a line-end or between a line-end and a line pattern. The bridge defect may mean that a plurality of line patterns that are supposed to be spaced apart from each other are connected to each other. The bridge defect may cause shorts in electrical signals, interference in electrical signals, and/or reduced yield of semiconductor devices.

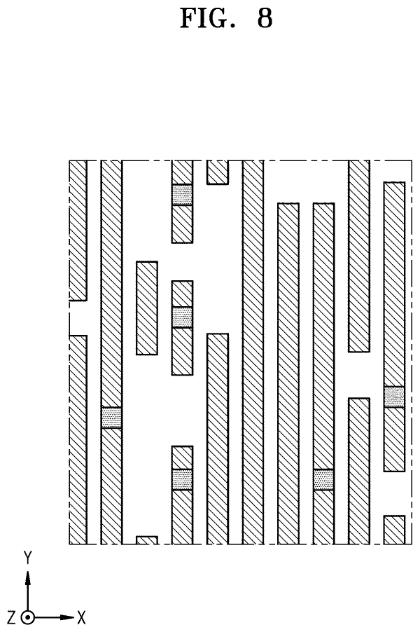

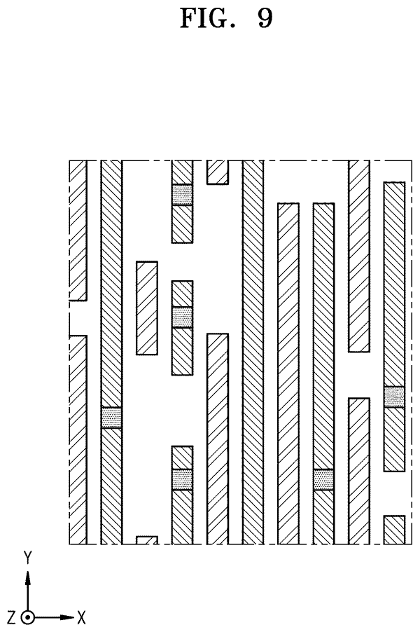

FIGS. 8 and 9 are conceptual diagrams for describing concepts of single exposure patterning and double exposure patterning. FIG. 8 shows line patterns of a critical pitch formed through a single exposure patterning process, and FIG. 9 shows line patterns of a critical pitch formed through a double exposure patterning process. Descriptions are provided with reference to FIGS. 1 to 7B together with FIGS. 8 and 9.

To distinguish between the single exposure patterning process and the double exposure patterning process, line patterns are indicated with the same hatching in FIG. 8, and line patterns are indicated with different hatching in FIG. 9.

Referring to FIGS. 8 and 9, the single exposure patterning process may mean a process of forming all of the line patterns within one mask and forming all of the line patterns through one exposure process. On the other hand, the double exposure patterning process may mean a process of forming line patterns by dividing the patterns into two masks and performing one exposure process per mask to form all of the line patterns through a total of two exposure processes.

Meanwhile, rectangles are indicated within some line patterns, and such rectangles may correspond to portions in which defects occur. For example, in a case of the single exposure patterning process, a P/O defect and/or a bridge defect may occur in the rectangles. Meanwhile, although not completely excluded, in a case of the double exposure patterning process, defects may not occur in the rectangles.

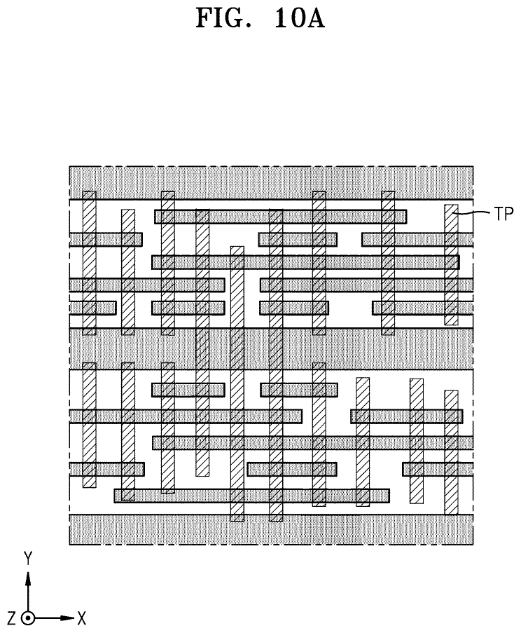

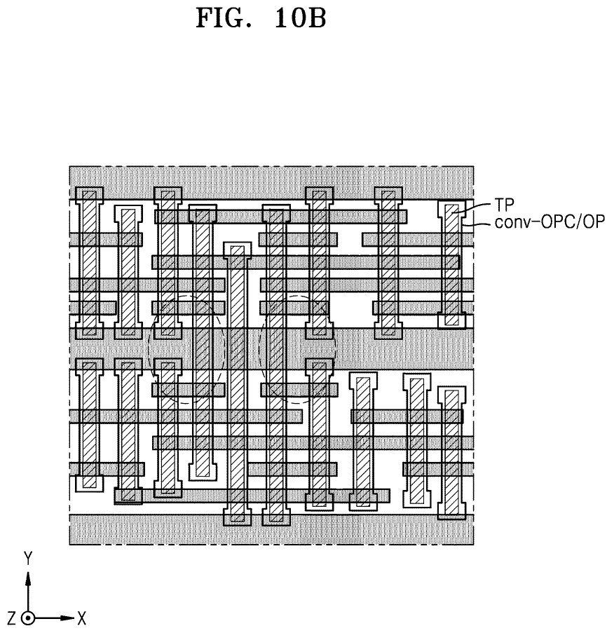

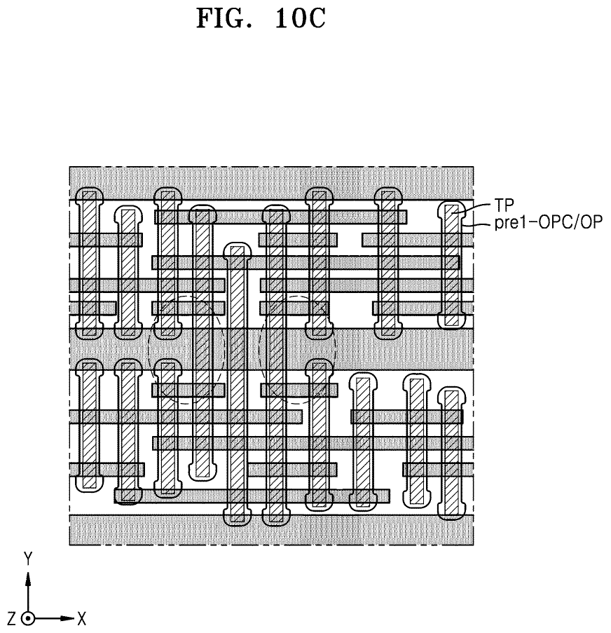

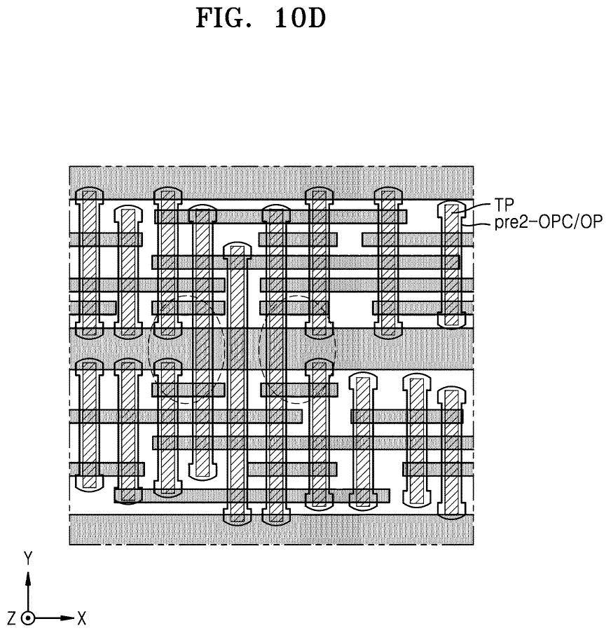

FIGS. 10A, 10B, 10C, and 10D are conceptual diagrams of a design layout for a target pattern, an OPC pattern according to the OPC method of the comparative example, and an OPC pattern according to the OPC method of the present embodiments. In particular, FIG. 10C is a conceptual diagram of an OPC pattern according to the OPC method described with reference to FIGS. 1 to 3, and FIG. 10D is a conceptual diagram of an OPC pattern according to the OPC method described with reference to FIGS. 4 to 6.

Referring to FIGS. 10A to 10D, FIG. 10A shows a design layout for the target pattern TP in a line and space form. In particular, the target pattern TP including line patterns extending in the second horizontal direction (Y direction) may correspond to a pattern to be formed on a substrate through the EUV process.

In an OPC pattern (conv-OPC/OP) obtained by applying the OPC method of the comparative example to a design layout of the target pattern TP, as shown in FIG. 10B, a line-end of a line pattern may have a hammer head shape, and a side line of the line pattern may have a jog shape due to small segments. The OPC method of the comparative example may include common OPC, for example, baseline OPC as described above (e.g., with reference to FIGS. 1 and 2). For reference, in FIG. 10B, a side line of the line pattern is displayed in a straight line rather than a jog, for convenience. When a single patterning process by EUV is performed on the OPC pattern (conv-OPC/OP) by the OPC method of the comparative example, a wiring bridge defect and/or a P/O defect may occur in line-ends of adjacent line patterns indicated by dotted ellipses in FIG. 10B and other line patterns adjacent to the line-ends.

On the other hand, as described above with reference to FIGS. 1 to 3, an OPC pattern (pre1-OPC/OP) obtained by applying the OPC method according to some embodiments may have a corner-rounded shape, as shown in FIG. 10C. In addition, as described above with reference to FIGS. 4 to 6, an OPC pattern (pre2-OPC/OP) obtained by applying the OPC method according to some embodiments may have a shape having curved line-ends (e.g., curved opposing line-ends), as shown in FIG. 10D. Accordingly, when a single patterning process by EUV is performed on the OPC patterns (pre1-OPC/OP and pre2-OPC/OP) by the OPC method according to some embodiments, a wiring bridge defect and a P/O defect may not occur in line-ends of adjacent line patterns indicated by dotted ellipses in FIGS. 10C and 10D and other line patterns adjacent to the line-ends.

Even when a single patterning process by EUV is performed on the OPC patterns (pre1-OPC/OP and pre2-OPC/OP) by the OPC method according to some embodiments, a distance between each line-end and an adjacent pattern may be different from each other. In general, when a single patterning process by EUV is performed, a distance between each line-end and an adjacent pattern may be equal to each other. However, the OPC patterns (pre1-OPC/OP and pre2-OPC/OP) by the OPC method according to some embodiments includes a corner-rounding operation, and a distance between each line-end and an adjacent pattern may be different from each other. In some embodiments, as shown in FIGS. 10C and 10D, at least two respective separation distances among a plurality of respective separation distances between opposing line-ends of the OPC patterns (pre1-OPC/OP and/or pre2-OPC/OP) may be different from each other.

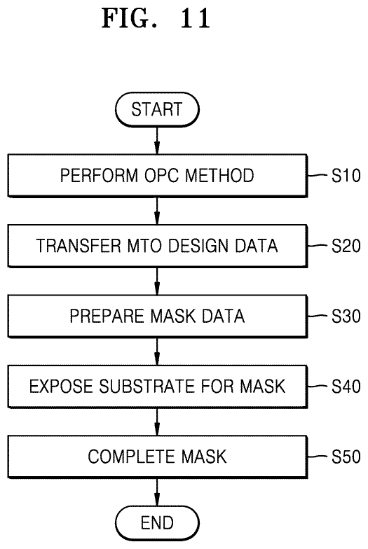

FIG. 11 is a flowchart schematically illustrating a process of a mask manufacturing method including an OPC method, according to some embodiments. Descriptions are provided with reference to FIGS. 1 to 6 together with FIG. 11, and those provided above with reference to FIGS. 1 to 10D are briefly explained or omitted.

Referring to FIG. 11, in the mask manufacturing method including the OPC method according to some embodiments (hereinafter, briefly referred to as a “mask manufacturing method”), first, the OPC method may be performed in operation S10. Performing the OPC method in operation S10 may include performing the OPC method of FIG. 1 and/or the OPC method of FIG. 4. Specifically, the OPC method of FIG. 1 may include an operation of receiving a design layout for a target pattern, an operation of obtaining a first OPC pattern (OPC/OP) by performing a baseline OPC, an operation of obtaining a second OPC pattern (CS-OPC/OP) by corner-rounding the first OPC pattern (OPC/OP), and an operation of obtaining a simulation contour of the second OPC pattern (CS-OPC/OP). In addition, the OPC method of FIG. 4 may include an operation of receiving a design layout for a target pattern, an operation of obtaining a first OPC pattern (OPC/OP) by performing a baseline OPC, an operation of performing a first DRC on the first OPC pattern (OPC/OP), an operation of obtaining a second OPC pattern (LEOCS-OPC/OP) by corner-rounding a line-end of the first OPC pattern (OPC/OP), an operation of performing a second DRC on the second OPC pattern (LEOCS-OPC/OP), and an operation of obtaining a simulation contour of the second OPC pattern (LEOCS-OPC/OP). Each of the operations of the OPC method is described in each of the operations of the OPC methods of FIGS. 1 and 4.

After the OPC method is performed, MTO design data may be transferred to a mask production team, in operation S20. In general, MTO may mean handing over data on a final design layout obtained through the OPC method to the mask production team to request mask production. Accordingly, in the mask manufacturing method according to some embodiments, MTO design data may ultimately mean an OPCed design layout obtained through the OPC method, or data related thereto. Such MTO design data may have a graphic data format used in electronic design automation (EDA) software or the like. For example, MTO design data may have a data format such as Graphic Data System II (GDS2) and Open Artwork System Interchange Standard (OASIS).

Thereafter, mask data preparation (MDP) may be performed in operation S30. For example, MDP may include i) format conversion called fracturing, ii) augmentation of barcodes for mechanical reading, standard mask patterns for inspection, job decks, etc., and iii) verification of automatic and manual methods. Here, a job deck may mean creating a text file regarding a series of instructions such as arrangement information of multiple mask files, standard dose, and exposure speed or method.

Format conversion, i.e., fracturing, may mean a process of fracturing MTO design data into each area and changing each area to a format for an electron beam exposer. For example, fracturing may include data manipulation such as scaling, sizing the data, rotating the data, reflecting patterns, and inverting colors. In a conversion process through fracturing, the data may be corrected for numerous systematic errors that may occur somewhere during a transfer from design data to an image on a wafer.

The data correction process for systematic errors is referred to as mask process correction (MPC), and may include, for example, line width adjustment called CD adjustment, and an operation of increasing pattern arrangement precision. Accordingly, fracturing may contribute to improving the quality of a final mask and may also be a process performed in advance for MPC. Here, the systematic errors may be caused by distortions occurring in an exposure process, a mask development and etching process, and a wafer imaging process.

Meanwhile, MDP may include MPC. As described above, the MPC refers to a process of correcting errors that occur during an exposure process, i.e., systematic errors. Here, the exposure process may be an overall concept that includes electron beam writing, development, etching, baking, etc. In addition, data processing may be performed before the exposure process. Data processing is a pre-processing process for mask data of a type and may include grammar check for mask data, exposure time prediction, etc.

After MDP, a substrate for a mask may be exposed based on the mask data, in operation S40. Here, the exposure may mean, for example, electron beam writing. Here, electron beam writing may be performed according to, for example, a gray writing method using a multi-beam mask writer (MBMW). In addition, electron beam writing may also be performed by using a variable shape beam (VSB) exposer.

Meanwhile, after the MDP operation, a process of converting mask data into pixel data may be performed before the exposure process (e.g., before exposing the substrate). The pixel data is data directly used for actual exposure and may include data on a shape to be exposed and data on a dose assigned to each shape. Here, the data on the shape may be bit-map data obtained by converting shape data, which is vector data, through rasterization or the like.

After exposing the substrate, a mask may be completed by performing a series of processes, in operation S50. For example, the series of processes may include processes such as development, etching, and cleaning. In addition, a series of process for mask production may include a metrology process and a defect inspection or defect repair process. Furthermore, the series of processes for mask production may include a pellicle application process. Here, the pellicle application process may mean a process of attaching, when it is confirmed through final cleaning and inspection that there are not contaminant particles or chemical stains, a pellicle to a mask surface to protect the mask from subsequent contamination during delivery of the mask and during a use life of the mask.

In the mask manufacturing method according to some embodiments, the OPC method may include a method of forming a CS-OPC pattern (CS-OPC/OP) by corner-rounding each first OPC pattern (OPC/OP) formed by baseline OPC. In addition, in the OPC method, each first OPC pattern (OPC/OP) formed by baseline OPC may be spaced apart from each other in an extension direction of a line pattern, and the OPC method according to some embodiments may include an operation of forming an LEOCS-OPC pattern (LEOCS-OPC/OP) for thinning an OPC pattern (OPC/OP) at line-end portions of line patterns adjacent to each other. Accordingly, the mask manufacturing method according to example embodiments may ensure a sufficient mass production margin for a target pattern of a critical pitch, so as to manufacture a mask capable of implementing the target pattern of the critical pitch through single exposure patterning. In particular, the mask manufacturing method according to example embodiments enables production of reliable EUV masks that do not generate P/O defects and wiring bridge defects even when the target pattern of the critical pitch is implemented through single exposure patterning in the EUV process.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. It will be understood that, although the terms first, second, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

While the inventive concepts have been particularly shown and described with reference to example embodiments thereof, it will be understood that various changes in form and details may be made therein without departing from the scope of the following claims.

1. An optical proximity correction (OPC) method, comprising:
receiving a design layout for a target pattern to be formed on a substrate;
obtaining a first OPC pattern by performing a baseline OPC on the design layout; and
obtaining a second OPC pattern by curving the first OPC pattern.

2. The OPC method of claim 1, wherein the first OPC pattern comprises a straight edge.

3. The OPC method of claim 1, wherein the second OPC pattern comprises a curved edge.

4. The OPC method of claim 1, wherein the curving of the first OPC pattern comprises a curvature-based corner-rounding method.

5. The OPC method of claim 1, further comprising:
obtaining a simulation contour for the second OPC pattern; and
determining whether a defect is present in the simulation contour.

6. The OPC method of claim 5, further comprising modifying the first OPC pattern when the defect is present.

7. The OPC method of claim 5, further comprising determining the second OPC pattern as a final OPC pattern when the defect is not present.

8. An optical proximity correction (OPC) method, comprising:
receiving a design layout for a target pattern to be formed on a substrate;
obtaining a first OPC pattern by performing a baseline OPC on the design layout;
obtaining a second OPC pattern by curving a line-end of the first OPC pattern;
obtaining a simulation contour for the second OPC pattern; and
determining whether a defect is present in the simulation contour.

9. The OPC method of claim 8, wherein the obtaining of the second OPC pattern comprises:
recognizing the line-end;
separating the line-end from a line pattern; and
corner-rounding the separated line-end.

10. The OPC method of claim 9, wherein the line-end is recognized by a first distance and a second distance,
wherein the first distance is a distance between the line-end and an adjacent line-end in a first horizontal direction parallel to an extension direction of the first OPC pattern, and
wherein the second distance is a distance between the line-end and an adjacent line pattern in a second horizontal direction different from the first horizontal direction.

11. The OPC method of claim 8, wherein the obtaining of the second OPC pattern comprises performing a first design rule check (DRC) to measure at least one of edges, corners, dimensions, or relative positions of the first OPC pattern.

12. The OPC method of claim 9, further comprising performing a second design rule check (DRC) on each of the corner-rounded separated line-end and the line pattern.

13. The OPC method of claim 9, wherein the obtaining of the second OPC pattern further comprises coupling the corner-rounded separated line-end and the line pattern to each other.

14. The OPC method of claim 8, wherein the first OPC pattern comprises a straight edge, and
wherein the second OPC pattern comprises a straight edge and a curved edge.

15. The OPC method of claim 9, wherein a height of a curved line-end of the second OPC pattern in a first horizontal direction is less than or equal to half a width of the curved line-end in a second horizontal direction different from the first horizontal direction.

16. The OPC method of claim 8, wherein a distance between a line-end of the second OPC pattern and an adjacent line pattern is greater than a distance between the line-end of the first OPC pattern and an adjacent line pattern.

17. The OPC method of claim 8, wherein a distance between the line-end of the first OPC pattern and an adjacent line pattern is equal to a distance between a line-end of the second OPC pattern and an adjacent line pattern.

18. A mask manufacturing method, comprising:
performing an optical proximity correction (OPC) method to obtain an OPCed design layout for a target pattern to be formed on a substrate;
transferring data on the OPCed design layout as mask tape-out (MTO) design data;
preparing mask data based on the MTO design data; and
performing an exposure on a substrate for a mask based on the mask data,
wherein the performing of the OPC method comprises:
receiving a design layout for the target pattern to be formed on the substrate;
obtaining a first OPC pattern by performing a baseline OPC on the design layout; and
obtaining a second OPC pattern by curving opposing line-ends of the first OPC pattern.

19. The mask manufacturing method of claim 18, wherein the mask is manufactured such that the target pattern is formed on the substrate by one extreme ultra-violet (EUV) exposure process.

20. The mask manufacturing method of claim 18, wherein at least two respective separation distances among a plurality of respective separation distances between opposing line-ends of the second OPC pattern are different from each other.
